(19) United States
(12) Patent Application Publication
(10) Pub. No.: US 2024/0162010 A1
(43) Pub. Date: May 16, 2024

(54) ADJUSTABLE DIELECTRIC CONSTANT CERAMIC WINDOW

(71) Applicant: Lam Research Corporation, Fremont, CA (US)

(72) Inventors: Chin-Yi Liu, San Jose, CA (US); Dan Marohl, San Jose, CA (US)

(21) Appl. No.: 18/550,664

(22) PCT Filed: Mar. 15, 2022
(86) PCT No.: PCT/US22/20366

§ 371 Date: Sep. 14, 2023

Related U.S. Application Data
(60) Provisional application No. 63/162,355, filed on Mar. 17, 2021.

(51) Int. Cl. H01J 37/32

(52) U.S. Cl. CPC H01J 37/32238; H01J 37/32119

(57) ABSTRACT

A dielectric window for a process chamber is provided. The dielectric window includes a disc-shaped body consisting of a first dielectric material having a first dielectric constant. An annular portion consisting of a second dielectric material having a second dielectric constant greater than the first dielectric constant is seated in the disc-shaped body. The dielectric window has a substantially constant thickness over a process region of the process chamber. The process region is an interior region of the process chamber in which a plasma is generated during processing of a substrate in the process chamber. The seating of the annular portion in the disc-shaped body is configured to maintain the substantially constant thickness of the dielectric window.

### FIELD OF THE INVENTION

Implementations of the present disclosure relate to an inductively coupled plasma chamber, and more specifically to a dielectric window having multiple materials that are configured to vary the dielectric constant, and thereby the RF coupling efficiency, across the dielectric window.

### DESCRIPTION OF THE RELATED ART

In the field of plasma processing, greater uniformity of plasma is sought to improve uniformity of processing (e.g. etch uniformity; deposition uniformity in plasma-assisted deposition processes, etc.) and consequent device yield. As feature sizes shrink and substrate/wafer sizes increase, the need for improved plasma uniformity is ever greater. The tolerance for radial non-uniformity of plasma etch processes, for example, is continually being lowered as manufacturers seek enhanced yield.

A prior solution to improve plasma uniformity in an inductively coupled plasma (ICP) process chamber relies on varying the shape of the dielectric window along the plasma-facing side of the dielectric window. This approach essentially changes the thickness of the dielectric window in order to vary the efficiency of power coupling into the process region. However, such a solution results in certain portions of the dielectric window protruding into the process region below the dielectric window. This can create problems with material accumulation (e.g. polymer buildup) around the protrusions. Further, such protrusions may interfere with gas flow in the chamber, and make it more challenging to fit other components (e.g., Faraday shield).

It is in this context that implementations of the disclosure arise.

### SUMMARY

Implementations of the present disclosure provide a dielectric window having multiple materials, wherein such materials can have different dielectric constants, thereby varying the RF coupling efficiency through the dielectric window.

In some implementations, a dielectric window for a process chamber is provided, including: a disc-shaped body consisting of a first dielectric material having a first dielectric constant; an annular portion consisting of a second dielectric material having a second dielectric constant greater than the first dielectric constant, the annular portion being seated in the disc-shaped body; wherein the dielectric window has a substantially constant thickness over a process region of the process chamber, the process region being an interior region of the process chamber in which a plasma is generated during processing of a substrate in the process chamber; wherein the seating of the annular portion in the disc-shaped body is configured to maintain the substantially constant thickness of the dielectric window.

In some implementations, a top surface of the disc-shaped body includes an annular recess that accommodates the annular portion.

In some implementations, the disc-shaped body and the annular portion are configured so that an efficiency of inductive coupling of power through the dielectric window is different for different radial sections of the dielectric window.

In some implementations, the different radial sections include a first section through which power is inductively coupled through the first dielectric material alone, and a second section through which power is inductively coupled through both of the first and the second dielectric materials.

In some implementations, the disc-shaped body defines a bottom surface of the dielectric window, such that the bottom surface of the dielectric window is defined from the first dielectric material alone.

In some implementations, a top surface of the dielectric window includes a surface region defined from the first dielectric material and a surface region defined from the second dielectric material.

In some implementations, the disc-shaped body spans a width of the process region, and wherein the annular portion does not span the width of the process region.

In some implementations, the annular portion is positioned to be substantially disposed below a coil that inductively couples power into the process region.

In some implementations, the disc-shaped body and the annular portion reduce radial non-uniformity of the plasma generated in the process region.

In some implementations, the annular portion defines an insert having a bottom contour shaped to conform to an upper contour of the disc-shaped body, so as to maintain the substantially constant thickness of the dielectric window.

In some implementations, the annular portion has a substantially rectangular cross-section.

In some implementations, the annular portion is embedded within the disc-shaped body.

In some implementations, a dielectric window for a process chamber is provided, including: a disc-shaped body consisting of a first dielectric material having a first dielectric constant; an annular cavity defined within the disc-shaped body, the annular cavity configured to contain a second dielectric material having a second dielectric constant greater than the first dielectric constant, the second dielectric material being a fluid.

In some implementations, the disc-shaped body and the annular cavity are configured so that an efficiency of inductive coupling of power through the dielectric window is different for different radial sections of the dielectric window.

In some implementations, the different radial sections include a first section through which power is inductively coupled through the first dielectric material alone, and a second section through which power is inductively coupled through both of the first and the second dielectric materials.

In some implementations, the disc-shaped body spans a width of the process region, and wherein the annular cavity does not span the width of the process region.

In some implementations, the annular cavity is positioned to be substantially disposed below a coil that inductively couples power into the process chamber.

In some implementations, the disc-shaped body and the annular cavity reduce radial non-uniformity of plasma generated in the process chamber.

In some implementations, the annular cavity has a substantially rectangular cross-section.

It will be appreciated that the foregoing represents a summary of certain non-limiting implementations of the disclosure. Additional implementations will be apparent to those skilled in the art in accordance with the scope of the present disclosure.

### BRIEF DESCRIPTION OF THE DRAWINGS

FIG. 1A illustrates a conceptual cross-section view of a dielectric window 100 for a plasma process chamber, in accordance with implementations of the disclosure.

FIG. 1B illustrates a conceptual cross-section view of a dielectric window 100 for a plasma process chamber, in accordance with implementations of the disclosure.

FIG. 2A illustrates a conceptual cross-section view of a dielectric window 100 for a plasma process chamber, having multiple concentric inserts, in accordance with implementations of the disclosure.

FIG. 2B illustrates a conceptual cross-section view of a dielectric window 100 for a plasma process chamber, having multiple concentric inserts, in accordance with implementations of the disclosure.

FIG. 3A illustrates a conceptual cross-section view of a dielectric window 100 for a plasma process chamber, having a central insert, in accordance with implementations of the disclosure.

FIG. 3B illustrates a conceptual cross-section view of a dielectric window 100 for a plasma process chamber, having a central insert, in accordance with implementations of the disclosure.

FIG. 3C illustrates a conceptual cross-section view of a dielectric window 100 for a plasma process chamber, having a central insert, in accordance with implementations of the disclosure.

FIG. 4A conceptually illustrates a cross-section view of a dielectric window 100 having an embedded channel for containing a material having a different dielectric constant, in accordance with implementations of the disclosure.

FIG. 4B conceptually illustrates a cross-section of a dielectric window 100 having multiple channels embedded therein, in accordance with implementations of the disclosure.

FIG. 4C conceptually illustrates a cross-section view of a dielectric window 100 having an embedded annular channel, in accordance with implementations of the disclosure.

FIG. 5A conceptually illustrates a cross-section view of a dielectric window 100 having an embedded cavity, in accordance with implementations of the disclosure.

FIG. 5B conceptually illustrates a cross-section view of a dielectric window 100 having an embedded cavity, in accordance with implementations of the disclosure.

FIG. 5C conceptually illustrates a cross-section view of a dielectric window 100 having an embedded cavity, in accordance with implementations of the disclosure.

FIG. 6A conceptually illustrates a cross-section view of a dielectric window 100 having an embedded channel in which fluid is circulated, in accordance with implementations of the disclosure.

FIG. 6B conceptually illustrates a cross-section view of a dielectric window 100 having multiple annular channels in which fluid can be circulated, in accordance with implementations of the disclosure.

FIG. 7 conceptually illustrates an inductively coupled plasma system, in accordance with implementations of the disclosure.

FIG. 8 shows a control module 800 for controlling the systems described herein, in accordance with implementations of the disclosure.

### DETAILED DESCRIPTION

In plasma processing of wafers/substrates, plasma uniformity can impact wafer uniformity. Previous attempts at controlling transformer coupled plasma (TCP) uniformity have relied upon changing the RF coil design or the dielectric window/lid shape. However, changing the dielectric window shape can increase the manufacturing complexity of the window and may further impact part lifetime. While changes to the RF coil may help improve the plasma uniformity, such changes can introduce additional unknown plasma coupling impacts.

In contrast to prior attempts at improving plasma uniformity, implementations of the present disclosure achieve changes in plasma uniformity by changing/adjusting the local dielectric constant in the window or material without altering the shape of the dielectric window nor changing the RF coil. In implementations of the disclosure, a local dielectric constant change is achieved using solid, liquid or gas phase materials to create a hybrid material window.

Thus, unlike current solutions that use RF coil changes or lid shape changes to attempt to improve wafer process uniformity, implementations in accordance with the present disclosure provide a hybrid material concept to change plasma coupling efficiency (e.g. as determined/defined based on power dissipated in the matching network and RF coil). More specifically, in some implementations, a material with a large difference in dielectric constant is introduced into the window to adjust the local dielectric constant at specific locations in the window, which impacts the RF coupling efficiency in a desirable manner so as to improve plasma uniformity and consequently overall process uniformity. In various implementations, the introduced materials can be solid, liquid or gas phase, or a combination thereof. In some implementations, the dielectric constant is adjustable through the introduction of different materials to suit different processes. Accordingly, implementations of the present disclosure enable improved on-wafer uniformity without changes in hardware design of components other than the window itself.

Without being bound by any particular theory of operation with respect to the presently disclosed implementations, nonetheless, for purposes of providing a broader understanding and possible mechanisms of operation, the following explanation is provided. In inductively coupled plasma (ICP) or transformer coupled plasma (TCP), plasma is generated by inducing electric currents through electromagnetic induction. In the case of a planar induction source, the electrode typically takes the form of a spiral coil disposed over a dielectric window, with power being coupled through the dielectric window into a process region of a process chamber. While a transformer is created by the coil outside the window and the induced currents inside the chamber, there is also capacitive coupling through the dielectric window. It is known from previous research that increasing the thickness of the dielectric window reduces the RF coupling efficiency. This can be understood in view of the capacitance equation, according to which capacitance is proportional to the dielectric constant as well as the area of overlapping plates, but inversely proportional to the distance between the plates. Hence, as window thickness increases there is decreased mutual inductance and reduced RF coupling efficiency. Though the effects of changing window thickness have been explored, adjustment of the dielectric constant as a technique for affecting RF coupling efficiency has not been explored. Again, without being bound by any particular theory of operation, it is contemplated that in implementations of the present disclosure, the dielectric constant is locally adjusted through the use of various materials having different dielectric constants, to thereby affect RF coupling efficiency. This is advantageous over previous techniques in that RF coupling efficiency can be locally changed without changing the chamber geometry or the thickness of the dielectric window, and therefore does not require redesign of other components of the plasma processing system.

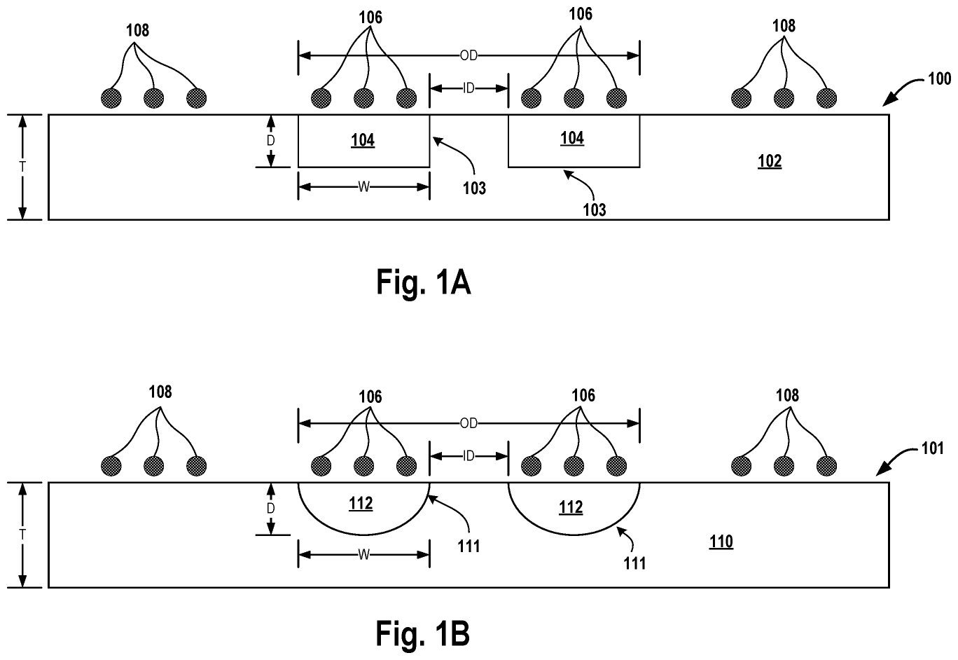

FIG. 1A illustrates a conceptual cross-section view of a dielectric window 100 for a plasma process chamber, in accordance with implementations of the disclosure.

In the illustrated implementation, the TCP coil of the process chamber is defined to include an inner coil 106 and an outer coil 108 disposed over the dielectric window 100. The inner and outer coils 106/108 can be independently powered and tuned to have different power settings in order to optimize power delivery into the chamber for a given plasma process. In some implementations, there are more than two coils. In some implementations, there is a single TCP coil.

In the illustrated implementation, the dielectric window 100 is composed of two portions, including a disc-shaped body 102, and an annular portion 104. The disc-shaped body 102 is formed from a first dielectric material (e.g. quartz, ceramic, or materials having a similar dielectric constant and similar coefficient of thermal expansion), and the annular portion 104 is formed from a second dielectric material having a different dielectric constant than that of the first dielectric material. In some implementations, the dielectric constant of the second material (for the annular portion 104) is greater than the dielectric constant of the first material (for the disc-shaped body 102).

As shown, the disc-shaped body 102 composes the main body or main portion of the dielectric window 100, and spans, at least substantially, the entire plasma process region below in which plasma is generated in the process chamber. The disc-shaped body 102 can be described as having a diameter spanning an area through which RF power is coupled from the coils above. Further, the annular portion 104 is formed as an insert and seated in the disc-shaped body 102, so that the dielectric window 100 has a substantially constant thickness T over a process region of the process chamber. It will be appreciated that the process region is an interior region of the process chamber in which a plasma is generated during processing of a substrate in the process chamber. The top surface of the disc-shaped body 102 includes an annular recess 103 that accommodates the annular portion 104. By seating the annular portion 104 into the disc-shaped body 102, the substantially constant thickness of the dielectric window 100 can be maintained, so that no effects from changes in the shape of the dielectric window 100 are realized.

It will be appreciated that by using different dielectric materials for the disc-shaped body 102 and annular portion 104, the dielectric constant through the dielectric window 100 is different for different radial sections of the dielectric window 100, and consequently, the efficiency of inductive coupling of power through the dielectric window is different for the different radial sections. That is, by introducing a second dielectric material into the dielectric window 100, there are different radial sections created including radial sections through which power is inductively coupled through the first dielectric material alone, and a section through which power is inductively coupled through both of the first and the second dielectric materials.

For example, in the illustrated implementation, the annular portion 104 is positioned substantially beneath the inner coil 106, such that the inner coil 106 is disposed directly over the annular portion 104. Thus, for a radial section extending from the inner diameter ID of the annular portion 104 to the outer diameter OD of the annular portion 104, power is coupled through both the second dielectric material of the annular portion as well as the first dielectric material of the disc-shaped body 102. Whereas for the radial portion extending from the center to the inner diameter ID of the annular portion 104, and for the radial portion extending from the outer diameter OD of the annular portion 104 to the periphery of the dielectric window 100, power is coupled through the first dielectric material of the disc-shaped body 102 alone.

It will be appreciated that the disc-shaped body defines the bottom (plasma-facing) surface of the dielectric window 100, such that the bottom surface of the dielectric window 100 is defined from the first dielectric material of the disc-shaped body alone. In this manner, the plasma-facing side of the dielectric window 100 exhibits no discontinuity in terms of surface structure, presenting a consistent plasma-facing surface that can be unchanged from previous designs, enabling the dielectric window 100 to be used without altering the chamber design. Furthermore, the plasma-facing surface of the dielectric window 100 can be formed without any protrusions or other contours that might present problems such as material buildup or interference with other interior componentry.

As indicated, the annular portion 104 is seated within the disc-shaped body 102 to such a depth within the disc-shaped body 102 so as to align the top surface of the annular portion 104 with the topmost surface of the disc-shaped body 102. In this manner, the thickness T of the dielectric window 100 is substantially constant from center to periphery of the dielectric window 100 that is over the process region of the process chamber. It will be appreciated that in the illustrated implementation, the top surface of the dielectric window 100 thus includes surface regions defined from the first dielectric material of the disc-shaped body 102 and a surface region defined from the second dielectric material of the annular portion 104. Thus, while the bottom surface of the dielectric window 100 is defined by a single material, the top surface of the dielectric window 100 is defined by multiple materials.

The configuration of the disc-shaped body 102 and the annular portion 104 are tuned to reduce radial non-uniformity of plasma generated in the process region. It will be appreciated that in various implementations the dimensions of the annular portion 104 and the disc-shaped body 102 can vary. In some implementations, the thickness T of the dielectric window 100 is in the range of about 1 to 2 inches (about 2 to 5 cm); in some implementations, the thickness of the dielectric window 100 is about 1.3 to 1.7 inches (about 3 to 4 cm); in some implementations, about 1.5 inches (about 3.8 cm). In some implementations, the thickness D of the annular portion 104 is in the range of about 0.5 to 1 inch (about 1 to 3 cm); in some implementations, about 0.7 to 0.8 inch (about 2 cm). In some implementations, the thickness D of the annular portion 104 is approximately one quarter to three quarters of the overall thickness T of the dielectric window 100. In some implementations, the thickness D of the annular portion 104 is approximately one-half of the overall thickness T of the dielectric window 100.

In some implementations, the annular portion 104 is formed as an insert having a bottom contour that is shaped to conform to the contour of the annular recess 103 of the disc-shaped body 102, so as to maintain the substantially constant thickness of the dielectric window 102. It will be appreciated that the top surface of the annular portion 104 is horizontal so as to be level with the uppermost surface of the disc-shaped body 102. Thus, in some implementations, the disc-shaped body 102 can be machined to form the annular recess 103, and the annular portion 104 can be formed to the matching shape of the recess. In some implementations, the annular portion 104 is interchangeable so that different materials can be substituted to provide different dielectric constants and different RF coupling efficiencies.

It is noted that in some implementations, the space between the RF coil (e.g. inner coil 106 and outer coil 108) and the dielectric window 100 is very small, e.g. on the order of less than about 0.1 inch (less than about 0.3 mm) (e.g. in some implementations, about 0.09 inch). It will be appreciated that in accordance with implementations of the disclosure, such small spacing can be maintained while varying the dielectric constant and the RF coupling efficiency across the dielectric window 100.

In the illustrated implementation, the annular portion 104 is shown to have a substantially rectangular cross-sectional shape. However, in other implementations, the annular portion 104 can have other types of cross-sectional shapes. In some implementations, the annular portion can be embedded within the disc-shaped body.

FIG. 1B illustrates a conceptual cross-section view of a dielectric window 101 for a plasma process chamber, in accordance with implementations of the disclosure.

In the illustrated implementation of FIG. 1B, the dielectric window 101 is composed of a disc-shaped body 110 and an annular portion 112. The annular portion 112 has a substantially semicircular or substantially semi-oval shaped cross-section, and is seated in the disc-shaped body 110 within the annular recess 111 that is formed on the top side of the disc-shaped body 110. The annular portion 112 is seated into the disc-shaped body 110 so that the dielectric window 101 has a constant thickness T, as shown, throughout the dielectric window 101 that is substantially over the process region of the process chamber.

From the top surface level of the dielectric window 101, the annular portion 112 may extend down to a thickness/depth D. The annular portion 112 extends radially from an inner diameter ID to an outer diameter OD, so as to have a radial width W. In some implementations, the annular portion 112 is positioned to be substantially disposed beneath the inner coil 106. In other implementations, the annular portion 112 can be configured so as to be partially disposed beneath the inner coil 106, or not disposed beneath the inner coil 106.

As noted, the shape of the annular portion can be configured to provide for a variable dielectric constant across the dielectric window 101, which can accordingly vary the RF coupling efficiency through the window.

In the presently described implementations, the dielectric constant of the annular portion differs from that of the disc-shaped body. In some implementations, the dielectric constant of the annular portion is greater than the dielectric constant of the disc-shaped body. In some implementations, the dielectric constant of the annular portion is greater than that of the disc-shaped body by a factor of 2×, 3×, 4×, 5× or greater.

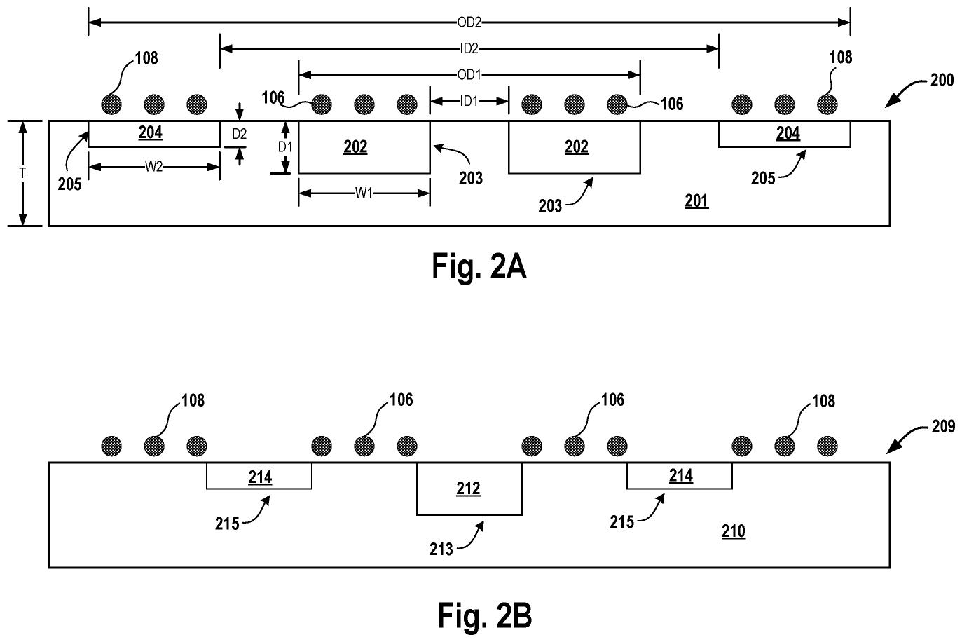

FIG. 2A illustrates a conceptual cross-section view of a dielectric window 200 for a plasma process chamber, having multiple concentric inserts, in accordance with implementations of the disclosure.

In the illustrated implementation, the dielectric window 200 is shown having two annular portions seated therein, including an inner annular portion 202 seated in an annular recess 203, and an outer annular portion 204 seated in an annular recess 205. The inner annular portion 202 and the outer annular portion 204 are configured to be seated in the disc-shaped body 201 such that the thickness T of the dielectric window 200 is maintained at a substantially constant amount across its total diameter.

The inner annular portion 202 has a radial width W1 that extends from an inner diameter ID1 to an outer diameter OD1 as shown. The outer annular portion 204 has a radial width W2 that extends from an inner diameter ID2 to an outer diameter OD2 as shown. In the illustrated implementation, the inner annular portion 202 is disposed below the inner coil 106, whereas the outer annular portion 204 is disposed below the outer coil 108. It will be appreciated that the inner coil 106 can be considered to extend radially from its innermost extent to its outermost extent, and that the radial region from the innermost to outermost extent is referenced for purposes of defining what is disposed below or not disposed below the inner coil 106. Therefore, when describing the inner annular portion 202 as being disposed below the inner coil 106, this means that the inner annular portion 202 is at least partially below the radial region defined by the inner coil 106. (It will be appreciated that a similar concept applies to the outer coil 108.)

In some implementations, as shown in the illustrated implementation, the thickness of the inner annular portion 202 is greater than the thickness of the outer annular portion 204. In other implementations, the thicknesses of the inner and outer annular portions 202 and 204 are substantially similar. In still other implementations, the thickness of the outer annular portion 204 is greater than the thickness of the inner annular portion 202. In some implementations, the inner and outer annular portions 202 and 204 consist of the same material; whereas in other implementations, the inner and outer annular portions 202 and 204 consist of different materials.

Each of the inner and outer annular portions 202 and 204 consists of a material having a dielectric constant different than that of the disc-shaped body 201. Furthermore, in some implementations, the inner and outer portions 202 and 204 can be formed from different materials. In some implementations, the dielectric constant of the inner or outer annular portions 202 and 204 is greater than the dielectric constant of the disc-shaped body 201. As noted in the present implementations, by providing materials with different dielectric constants for the annular portions, the dielectric window 200 would have varied dielectric constant across its radius, which in turn provides varied RF coupling efficiency through the dielectric window 200.

Though in the illustrated implementation, two annular portions are shown which are defined as inserts formed from a material with a different dielectric constant than the disc-shaped body 201, it will be appreciated that in other implementations, there can be more than two annular portions, which can also have variably defined thicknesses, annular widths, material compositions, and concentric placements.

FIG. 2B illustrates a conceptual cross-section view of a dielectric window 100 for a plasma process chamber, having multiple concentric inserts, in accordance with implementations of the disclosure.

In the illustrated implementation, the dielectric window 209 is defined to include a disc-shaped body 210 which forms the main body of the dielectric window 209, along with a disc-shaped insert 212 that is centrally positioned within the disc-shaped body 210 in a recess 213 defined along the top of the disc-shaped body 210. As shown, the disc-shaped insert 212 is positioned in the center of the dielectric window 209 and further define so as to be not substantially disposed below the inner coil 106. In the illustrated implementation, the disc-shaped insert 212 is rather disposed below the center gap of the inner coil 106.

Additionally, in the illustrated implementation, an annular insert 214 is seated within an annular recess 215. As shown, the annular insert 214 is positioned so as not to be substantially disposed below either of the inner coil 106 or outer coil 108. In the illustrated implementation, the annular insert 214 is disposed below the gap between the inner coil 106 and outer coil 108.

In some implementations, the thickness of disc-shaped insert 212 is greater than the thickness of the annular insert 214. In some implementations, the thickness of disc-shaped insert 212 and the annular insert 214 are substantially similar.

Similar to other implementations described herein, the disc-shaped insert 212 and the annular insert 214 are defined from materials having different dielectric constants than the disc-shaped body 210.

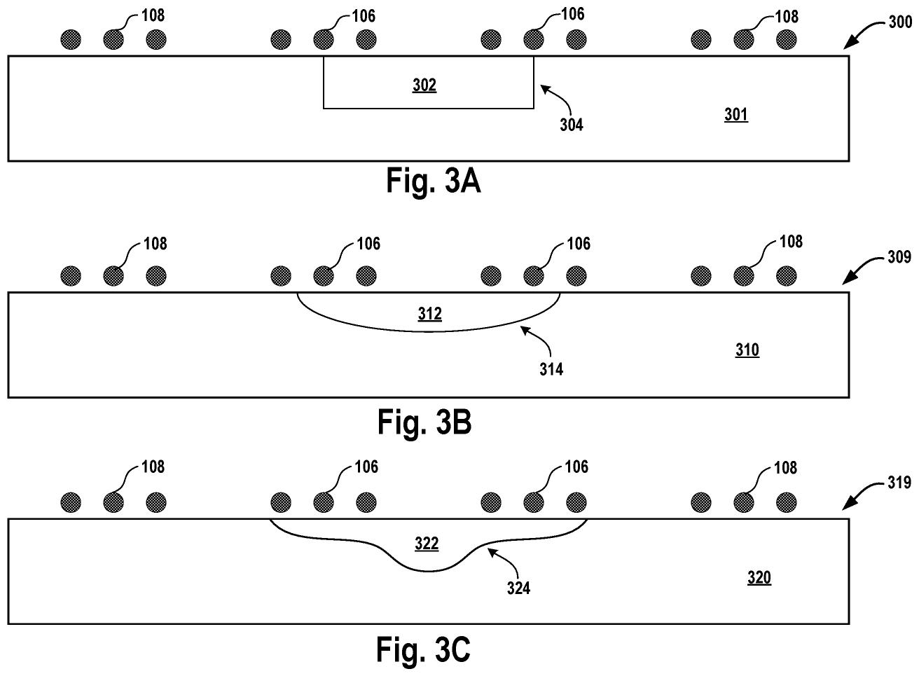

FIG. 3A illustrates a conceptual cross-section view of a dielectric window 300 for a plasma process chamber, having a central insert, in accordance with certain implementations of the disclosure.

In the illustrated implementation, the dielectric window 300 includes a centrally positioned disc insert 302 that is seated within a recess 304 that is centrally positioned along the top of the disc-shaped body 301. As shown, the disc insert 302 extends from the center of the dielectric window 100 which is not disposed below the inner coil 106, outward to a diameter that is substantially disposed below the inner coil 106. Further, the diameter of the disc insert 302 is configured so as to partially overlap the radial region of the inner coil 106, so that below the inner coil 106, the dielectric window 300 is configured so that the radial region of the inner coil 106 is partially over the disc insert 302 and partially over the disc-shaped body 301. As such, RF coupling below the inner coil 106 is partially through both materials of the disc insert 302 and the disc-shaped body 301, and partially through the material of the disc-shaped body 301 alone.

It will be appreciated that the disc insert 302 is formed from a material having a different dielectric constant than the disc-shaped body 301, so as to provide for a different RF coupling efficiency through the dielectric window 300, as previously described.

FIG. 3B illustrates a conceptual cross-section view of a dielectric window 309 for a plasma process chamber, having a central insert, in accordance with implementations of the disclosure.

In the illustrated implementation, a disc insert 312 is disposed within a recess 314 of the disc-shaped body 310, so that the disc insert 312 is centrally positioned within the overall dielectric window 309. The disc insert 312 is configured to have a thickness that varies across its radius. More specifically, in the illustrated implementation, the disc insert 312 has a thickness that decreases from center to the outer diameter of the disc insert 312. Furthermore, in the illustrated implementation, the disc insert 312 has a cross-sectional shape through the center that is substantially bowl-shaped, exhibiting a convex curvature along its underside. In this manner, RF coupling efficiency through the dielectric window 309 continually varies in the region that includes the disc insert 312 from center to edge.

In the illustrated implementation, the diameter of the disc insert 312 is configured so that the disc insert 312 extends from the center to a position below the inner coil 106. However, it will be appreciated that in other implementations, the diameter of the disc insert 312 can extend to greater or shorter lengths, including diameters which extend to or beyond the outer diameter of the inner coil 106, or diameters which extend to less than the inner diameter of the inner coil 106.

FIG. 3C illustrates a conceptual cross-section view of a dielectric window 319 for a plasma process chamber, having a central insert, in accordance with implementations of the disclosure.

In the illustrated implementation, a disc insert 322 is shown disposed in a recess 324 along the top surface of a disc-shaped body 320. The contour along the underside of the disc insert 322 as shown, is configured to have a convex curvature with an additional bulge in the center.

It will be appreciated that as shown and described, in various implementations the number, placement, size, contours and material composition of the inserts can vary. Various non-limiting examples have been provided by way of example without limitation, but it will be appreciated that other configurations are possible. It will be appreciated that the various parameters of the inserts can be specifically tuned for different processes and configured to mitigate non-uniformity by varying the RF power coupling efficiency across the radial span of the dielectric window. In the case where the dielectric constant of the insert is greater than that of the main body, then the total dielectric constant across those regions of the dielectric window that include the insert will be greater than those regions that do not include the insert. Hence, the RF coupling efficiency is reduced/dampened across those regions of the dielectric window that include the insert versus those regions that do not include the insert. Moreover, the RF coupling efficiency can be changed to varying extents by varying the thickness of the insert in a particular region, such that increasing the thickness of the insert increase resistance and thus reduces RF coupling efficiency for that particular region.

In some implementations, the RF coupling efficiency across the dielectric window translates or correlates, at least approximately, to the plasma density produced in the chamber beneath the dielectric window. That is, in some implementations, plasma density increases with increasing RF coupling efficiency, so that reducing RF coupling efficiency through the placement of inserts as presently described will cause a reduction in plasma density in the regions approximately below the regions of the inserts, with a varying extent of plasma density reduction approximately correlated to the thickness of the insert in a given region of the dielectric window.

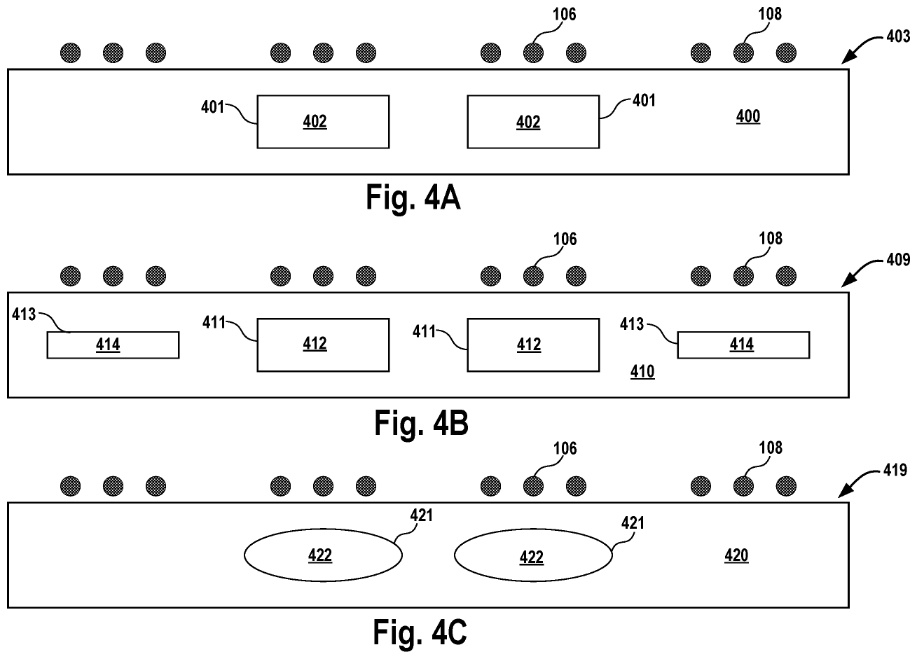

FIG. 4A conceptually illustrates a cross-section view of a dielectric window 403 having an embedded channel for containing a material having a different dielectric constant, in accordance with implementations of the disclosure.

In the illustrated implementation, the dielectric window 403 includes a disc-shaped body 400 having an annular channel 401 embedded within. The annular channel 401 is filled with a material 402 having a different dielectric constant than that of the disc-shaped body 400. In some implementations, wherein the material 402 is a solid, then the material 402 essentially forms an insert similar to the inserts described above, but embedded within the disc-shaped body as opposed to being disposed along the top surface of the dielectric window 100.

However, in other implementations, as the material 402 is embedded within the disc-shaped body 400, the material 402 can be a gel, liquid or gas having a dielectric constant different than the dielectric constant of the disc-shaped body 400. In some implementations, the annular channel 401 can be filled with a combination of multiple materials, such as a combination of a gel, liquid or gas (e.g. a gel and a gas, a liquid and a gas). It will be appreciated that the relative amounts of such materials used in combination can be tailored to achieve a desired variance in dielectric constant across the dielectric window (e.g. approximately 1:1, 1:2, 1:3, etc. by volume for any two materials used to fill the annular channel).

Generally, it is easier to achieve a larger difference in dielectric constant between a solid and liquid/gas material (e.g. dielectric constant of quartz is approximately 9, whereas dielectric constant of water is approximately 80), than between a solid and another solid material. In other words, it will be appreciated that in some implementations, the dielectric constants of gels, liquids, or gases can provide greater selection of materials having higher differences in dielectric constant versus the dielectric constant of the solid material of the disc-shaped body (e.g. quartz, ceramic, etc.).

The effect of the material 402 is similar to that described above with respect to the aforementioned inserts, which is to alter the effective dielectric constant across the dielectric window 403 for the radial region that includes the material 402 versus the radial regions that do not include the material 402, and thereby alter the RF coupling efficiency across the dielectric window 403 accordingly.

It will be appreciated that the placement, thickness, and radial width of the annular channel 401 can be configured or tuned to provide a desired alteration in the RF coupling efficiency for a particular radial section of the dielectric window 403. In the illustrated implementation, the annular channel 401 is substantially disposed below the inner coil 106. However, in other implementations, the annular channel 401 can be disposed in other locations, and may (or may not) partially or fully overlap the inner and/or outer coils 106 and 108.

FIG. 4B conceptually illustrates a cross-section of a dielectric window 409 having multiple channels embedded therein, in accordance with implementations of the disclosure.

In the illustrated implementation, the dielectric window 409 is defined having an inner annular channel/cavity 411 that is filled with a material 412, and an outer annular channel 413 that is filled with a material 414. In the illustrated implementation, the thickness of the inner annular channel 411 is greater than the thickness of the outer annular channel 413. Whereas in other implementations, the thickness of the inner annular channel 411 is approximately the same as or less than the thickness of the outer annular channel 413. As shown, the inner and outer annular channels 411 and 413 are substantially disposed below the inner and outer coils 106 and 108, respectively. However, in other implementations, the placement of the annular channels can vary from that shown, including being partially disposed below the inner or outer coils. Further, in some implementations, the radial widths of the inner and outer annular channels 411 and 413 can vary.

In various implementations, the various parameters of the annular channels can be tailored to achieve a desired effect on the RF coupling efficiency, such as local reduction/dampening/attenuation. Such parameters can include, by way of example without limitation, the number of channels, radial placement, vertical placement (within the overall thickness of the dielectric window 409), radial width, thickness, cross-sectional shape, etc. These parameters can be adjusted or tuned to achieve a desired RF coupling efficiency profile, and/or a desired plasma density profile in the plasma produced in the process chamber.

Additional shapes and configurations of embedded channels or cavities are described below, which are provided by way of example without limitation, to demonstrate certain particular implementations.

FIG. 4C conceptually illustrates a cross-section view of a dielectric window 100 having an embedded annular channel, in accordance with implementations of the disclosure.

In the illustrated implementation, dielectric window 419 is defined having an annular channel 421 formed within the disc-shaped body 420, the annular channel 422 being filled with a material 422 having a different dielectric constant than that of the disc-shaped body 420. As shown, the annular channel 421 has a substantially ovaloid shape. In some implementations, as also shown in the illustrated implementation, the annular channel 421 is substantially disposed below the inner coil 106.

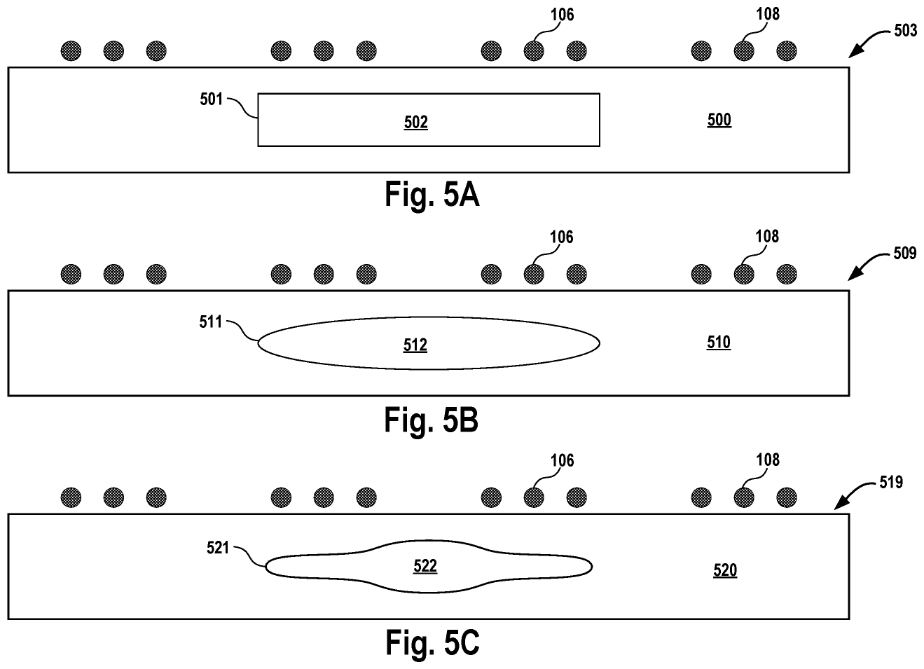

FIG. 5A conceptually illustrates a cross-section view of a dielectric window 503 having an embedded cavity, in accordance with implementations of the disclosure.

In the illustrated implementation, the dielectric window 503 is defined by the disc-shaped body 500 having a cavity 501 that is filled with a material 502. As shown, the cavity 501 is also substantially disc-shaped, having a substantially rectangular cross-sectional shape. Further in the illustrated implementation, the diameter of the cavity 501 is configured so as to extend at least approximately to an outer diameter of the inner coil 106.

FIG. 5B conceptually illustrates a cross-section view of a dielectric window 509 having an embedded cavity, in accordance with implementations of the disclosure.

In the illustrated implementation, the dielectric window 509 is defined by a disc-shaped body 510 having a cavity 511 that is filled with a material 512. As shown, the disc-shaped cavity 511 has a substantially ovaloid cross-sectional shape.

FIG. 5C conceptually illustrates a cross-section view of a dielectric window 519 having an embedded cavity, in accordance with implementations of the disclosure.

In the illustrated implementation, the dielectric window 519 is defined by a disc-shaped body 520 having a cavity 521 that is filled with a material 522. The disc-shaped cavity 521 has a cross-sectional shape that is substantially ovaloid with a central bulge.

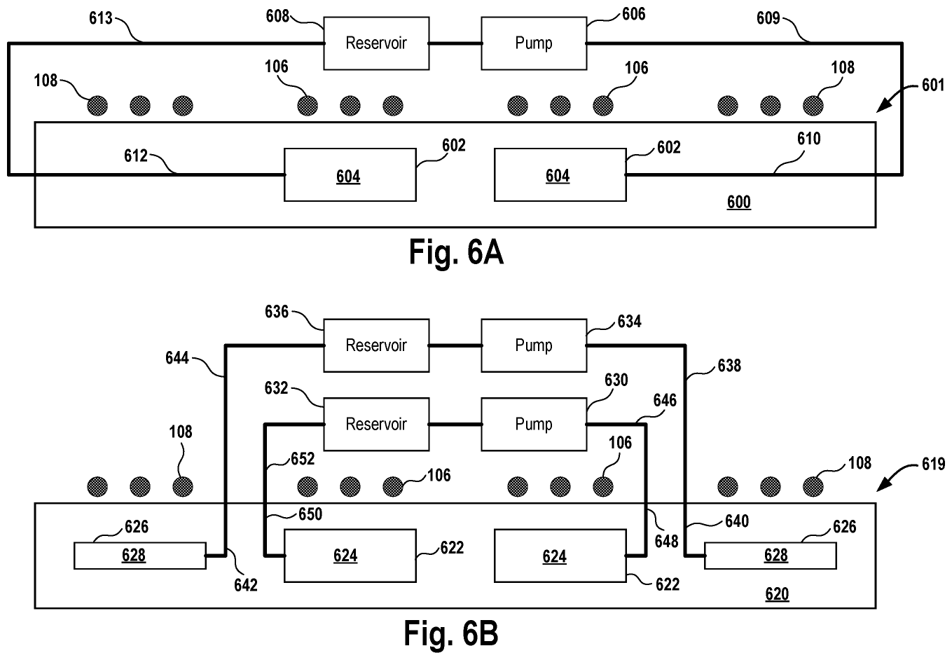

FIG. 6A conceptually illustrates a cross-section view of a dielectric window 601 having an embedded channel in which fluid is circulated, in accordance with implementations of the disclosure.

In the illustrated implementation, the dielectric window 601 is defined by a disc-shaped body 600 having an annular channel 602 that is filled with a fluid material 604 (similar to the implementation of FIG. 4A). Additionally, the annular channel 602 is configured to have its fluid material circulated by a pump 606. That is, the fluid material is pumped into and out of the annular channel 602 by the pump 606. In some implementations, the pump 606 pumps the fluid material from a reservoir 608 through a hose 609 that connects to an inlet channel 610 defined within the disc-shaped body 600, that connects to the annular channel 602. Thus, the fluid material 604 is pumped through the inlet channel 610 into the annular channel 602.

An outlet channel 612 connects from the annular channel 602 to a hose 613, that connects to the reservoir 608. Thus, the fluid material flows out of the annular channel 602 via the outlet channel 612 and the hose 613, returning the fluid material to the reservoir 608. In this manner, the fluid material can be circulated into and out of the annular channel 602. It will be appreciated that though a single inlet channel and single outlet channel are shown in the illustrated implementation, there can be multiple inlet channels and/or multiple outlet channels (and multiple corresponding hoses, accordingly). Furthermore, there can be multiple pumps and/or reservoirs in some implementations. Additionally, though in the illustrated implementation, the inlet channel 610 and outlet channel 612 are shown as horizontal radially oriented channels that connect from the annular channel 602 to the outer circumference of the dielectric window 601, in other implementations, the inlet/outlet channels can have other configurations, such as being vertically oriented channels disposed over the annular channel 602.

In some implementations, the reservoir 608 or the pump 606 includes a cooling mechanism to cool the fluid material. In some implementations, the cooling mechanism can include passive or active cooling mechanisms, such as a radiator, heat sink, heat exchanger, coolant, refrigerant, etc. This can be useful for maintaining the temperature of the fluid material in a desired temperature range, and for preventing boiling of the fluid material due to heating occurring in the dielectric window 601 during operation.

In some implementations, the fluid material can be changed from a first fluid material to a second fluid material. In some implementations, a second reservoir (not shown) is provided, and optionally, a second pump (not shown), from which a second fluid material is flowed into the annular channel 604, and optionally circulated. In this manner, different fluid materials having different dielectric constants can be supplied to the annular channel 602 depending upon the particular process, so that the selection of fluid material for a given process can be optimized. In this way, by changing the fluid material supplied to the annular channel 602, the local dielectric constant is dynamically adjustable, and consequently the RF coupling efficiency is adjustable through the introduction of different fluids into the annular channel 602.

In some implementations, multiple fluids are introduced into the annular channel in a predefined ratio to provide a mixture/solution having a predefined dielectric constant and thereby provide a desired local RF coupling efficiency. In some implementations, the ratio of the multiple fluids can be varied (e.g. by pumping the fluids at different rates into the annular channel) in order to vary the dielectric constant of the solution/mixture, and thereby vary the RF coupling efficiency accordingly. This can provide an additional level of tunability and dynamic adjustability of the RF coupling efficiency across the region having the annular channel 602.

FIG. 6B conceptually illustrates a cross-section view of a dielectric window 619 having multiple annular channels in which fluid can be circulated, in accordance with implementations of the disclosure.

The implementation of FIG. 6B includes an inner annular channel 622 in which a fluid material 624 is disposed, and an outer annular channel 626 in which a fluid material 628 is disposed. The inner annular channel 622 and the outer annular channel 628 can have similar or different thicknesses, though as shown in the illustrated implementation, the thickness of the inner annular channel 622 is greater than the thickness of the outer annular channel 626. A pump 630 circulates the fluid material 624 in the inner annular channel 622, pumping the fluid material 624 from a reservoir 632 through an inlet hose 646 into an inlet channel 648 into the inner annular channel 622, and out of the inner annular channel 622 via an outlet channel 650 to an outlet hose 652 that connects to the reservoir 632. In some implementations, the reservoir and/or the pump can include a cooling mechanism to cool the fluid material 624.

Similarly, a pump 634 circulates the fluid material 628 in the outer annular channel 626, pumping the fluid material 628 from a reservoir 636 through an inlet hose 638 into an inlet channel 640 into the outer annular channel 626, and out of the outer annular channel 626 via an outlet channel 642 to an outlet hose 644 that connects to the reservoir 636. In some implementations, the reservoir and/or the pump can include a cooling mechanism to cool the fluid material 628.

In some implementations, the fluid material 624 and the fluid material 628 are the same material. Whereas in other implementations, the fluid material 624 and the fluid material 628 are different materials. As previously described with reference to the implementation of FIG. 6A, the fluid material 624 and/or the fluid material 628 can be changed from one fluid to another fluid in order to tune or dynamically adjust the RF coupling efficiency, and may further employ mixtures/solutions to provide variability as previously described.

Though specific implementations have been described as including mechanisms for circulating and cooling fluids within channels/cavities defined within a dielectric window 100, it will be appreciated that such can be applied to any of the other embedded channel/cavity configurations described herein.

Further, while inserts and channels/cavities have been described having various radial contours and configurations, in still other implementations, the inserts and channels/cavities can have varied azimuthal profiles. That is, the parameters of a given insert or channel (e.g. thickness, radial width, contour, shape, material composition, etc.) can be varied along the azimuth or along an azimuthal direction (e.g. clockwise or counterclockwise direction).

Further, in some implementations, the inserts or channels/cavities can be discontinuous along an azimuth or azimuthal direction. In such implementations, a given radial portion of the dielectric window 619 may include one or more arc segments of inserts or channels.

As has been described, the inserts and channels are composed of or filled with materials having a dielectric constant different from that of the main disc-shaped body of the dielectric window 619, which is typically composed of quartz or a ceramic. It will be appreciated that any of various solid, liquid, or gaseous materials are contemplated in this regard. Furthermore, though a difference in dielectric constant has been generally described, in some implementations for which the material is capable of being changed from one material to another, it is possible to introduce a material having a similar dielectric constant to that of the main disc-shaped body, for example, for purposes of adjusting the RF coupling efficiency profile to suit a particular process. A non-exhaustive list of possible materials is provided below at Table 1, from which the inserts may be composed, or with which the channels/cavities may be filled.

TABLE 1

| | Dielectric |
|---|---|
| | Constant, Er |
| Material | D 2520-95 |
| CaTi | 200.0 |
| TiO2 | 90.0 |
| BaSmTi | 77.0 |
| BaSmTi | 76.5 |
| ZrTiSn | 37.0 |
| ZrTiSn | 37.0 |
| Zirconia | 29 |
| MgTi | 15.0 |
| AL2O3 98% | 9.4 |
| AL2O3 95% | 9.2 |
| AL Nitride | 8.6 |
| AL2O3 74% | 7.0 |
| MgSi | 6.5 |

Various techniques can be utilized to form a dielectric window in accordance with implementations of the disclosure. These include any of various ceramic forming techniques such as powder forming/molding. In some implementations, the dielectric window can be 3D printed, such as by 3D printing two types of ceramics or 3D printing channels within the dielectric window.

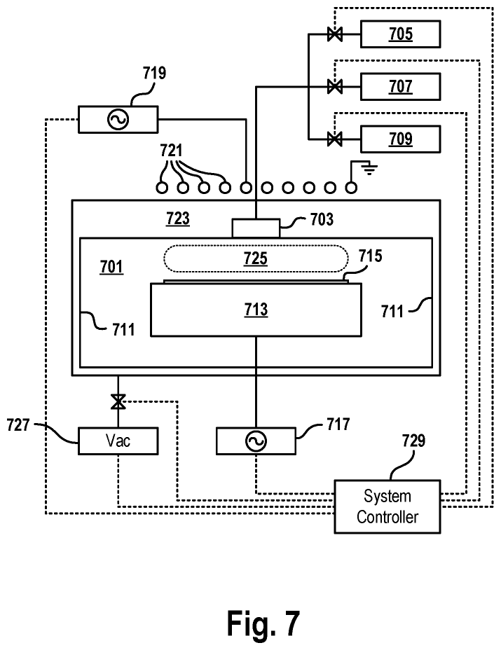

FIG. 7 conceptually illustrates an inductively coupled plasma system, in accordance with implementations of the disclosure.

Various implementations described herein may be performed in an inductively coupled plasma (ICP) system. With reference to FIG. 7, an example ICP deposition system or apparatus may include a chamber 701 having a gas injector/showerhead/nozzle 703 for distributing gases (705, 707, 709) (e.g. precursor, oxidant, and purge gases) or other chemistries into the chamber 701, chamber walls 711, a chuck 713 for holding a substrate or wafer 715 to be processed which may include electrostatic electrodes for chucking and dechucking a wafer. The chuck 713 is heated for thermal control, enabling heating of the substrate 715 to a desired temperature. In some implementations, the chuck 713 may be electrically charged using an RF power supply 717 to provide a bias voltage in accordance with implementations of the disclosure.

An RF power supply 719 is configured to supply power to an RF antenna/coil 721, disposed over a dielectric window 723 to generate a plasma 725 in the process space over the substrate 715. In some implementations, the chamber walls are heated to support thermal management and efficiency. A vacuum source 727 provides a vacuum to evacuate gases from the chamber 701. The system or apparatus may include a system controller 729 for controlling some or all of the operations of the chamber or apparatus such as modulating the chamber pressure, inert gas flow, plasma power, plasma frequency, reactive gas flow (e.g., precursor, oxidant, etc.); bias power, temperature, vacuum settings; and other process conditions.

In some implementations, a system/apparatus may include more than one chamber for processing substrates.

For purposes of throughput, ALD systems typically employ small volume chambers that can be rapidly filled and purged. However, ICP reactors tend to have significantly higher volume. Thus, there is the issue of how to enable fast switching of gases for ALD in a comparatively high volume system. One technique is to continuously purge the non-process volume space, so that only the process volume space that is directly over the wafer/substrate needs to be effectively purged during the purge operations of the ALD cycle. The process volume can be separated from the non-process volume space by an air curtain. Furthermore, fast gas exchanges can be employed, modulating gas flows and pressures to speed delivery and removal of gases from the process volume.

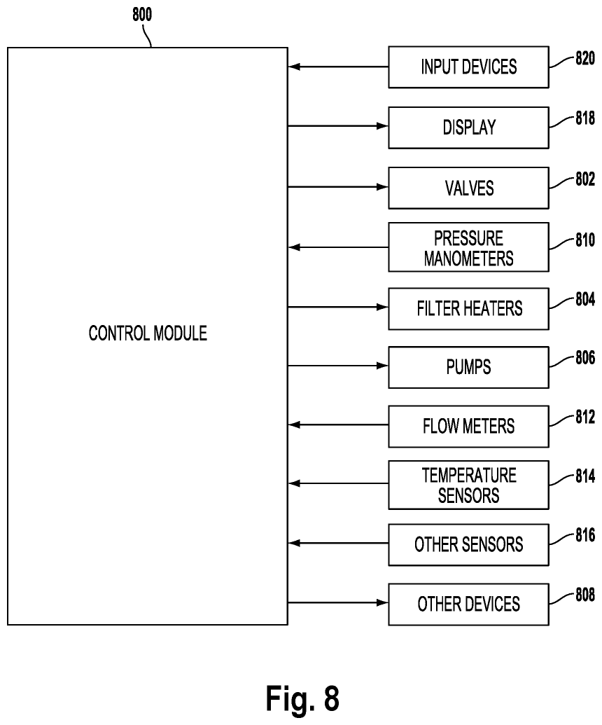

FIG. 8 shows a control module 800 for controlling the systems described herein, in accordance with implementations of the disclosure.

For instance, the control module 800 may include a processor, memory and one or more interfaces. The control module 800 may be employed to control devices in the system based in part on sensed values. For example, the control module 800 may control one or more of valves 802, filter heaters 804, pumps 806, and other devices 808 based on the sensed values and other control parameters. The control module 800 receives the sensed values from, for example only, pressure manometers 810, flow meters 812, temperature sensors 814, and/or other sensors 816. The control module 800 may also be employed to control process conditions during reactant delivery and plasma processing. The control module 800 will typically include one or more memory devices and one or more processors.

The control module 800 may control activities of the reactant delivery system and plasma processing apparatus. The control module 800 executes computer programs including sets of instructions for controlling process timing, delivery system temperature, pressure differentials across the filters, valve positions, mixture of gases, chamber pressure, chamber temperature, wafer temperature, RF power levels, wafer ESC or pedestal position, and other parameters of a particular process. The control module 800 may also monitor the pressure differential and automatically switch vapor reactant delivery from one or more paths to one or more other paths. Other computer programs stored on memory devices associated with the control module 800 may be employed in some implementations.

Typically there will be a user interface associated with the control module 800. The user interface may include a display 818 (e.g. a display screen and/or graphical software displays of the apparatus and/or process conditions), and user input devices 820 such as pointing devices, keyboards, touch screens, microphones, etc.

Computer programs for controlling delivery of reactant, plasma processing and other processes in a process sequence can be written in any conventional computer readable programming language: for example, assembly language, C, C++, Pascal, Fortran or others. Compiled object code or script is executed by the processor to perform the tasks identified in the program.

The control module parameters relate to process conditions such as, for example, filter pressure differentials, process gas composition and flow rates, temperature, pressure, plasma conditions such as RF power levels and the RF frequency, cooling gas pressure, and chamber wall temperature.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

Although the foregoing implementations have been described in some detail for purposes of clarity of understanding, it will be apparent that certain changes and modifications may be practiced within the scope of the disclosed implementations. It should be noted that there are many alternative ways of implementing the processes, systems, and apparatus of the present implementations. Accordingly, the present implementations are to be considered as illustrative and not restrictive, and the implementations are not to be limited to the details given herein.

1. A dielectric window for a process chamber, comprising:
a disc-shaped body consisting of a first dielectric material having a first dielectric constant;
an annular portion consisting of a second dielectric material having a second dielectric constant greater than the first dielectric constant, the annular portion being seated in the disc-shaped body;
wherein the dielectric window has a substantially constant thickness over a process region of the process chamber, the process region being an interior region of the process chamber in which a plasma is generated during processing of a substrate in the process chamber;
wherein the seating of the annular portion in the disc-shaped body is configured to maintain the substantially constant thickness of the dielectric window.

2. The dielectric window of claim 1, wherein a top surface of the disc-shaped body includes an annular recess that accommodates the annular portion.

3. The dielectric window of claim 1, wherein the disc-shaped body and the annular portion are configured so that an efficiency of inductive coupling of power through the dielectric window is different for different radial sections of the dielectric window.

4. The dielectric window of claim 3, wherein the different radial sections include a first section through which power is inductively coupled through the first dielectric material alone, and a second section through which power is inductively coupled through both of the first and the second dielectric materials.

5. The dielectric window of claim 1, wherein the disc-shaped body defines a bottom surface of the dielectric window, such that the bottom surface of the dielectric window is defined from the first dielectric material alone.

6. The dielectric window of claim 1, wherein a top surface of the dielectric window includes a surface region defined from the first dielectric material and a surface region defined from the second dielectric material.

7. The dielectric window of claim 1, wherein the disc-shaped body spans a width of the process region, and wherein the annular portion does not span the width of the process region.

8. The dielectric window of claim 1, wherein the annular portion is positioned to be substantially disposed below a coil that inductively couples power into the process region.

9. The dielectric window of claim 1, wherein the disc-shaped body and the annular portion reduce radial non-uniformity of the plasma generated in the process region.

10. The dielectric window of claim 1, wherein the annular portion defines an insert having a bottom contour shaped to conform to an upper contour of the disc-shaped body, so as to maintain the substantially constant thickness of the dielectric window.

11. The dielectric window of claim 1, wherein the annular portion has a substantially rectangular cross-section.

12. The dielectric window of claim 1, wherein the annular portion is embedded within the disc-shaped body.

13. A dielectric window for a process chamber, comprising:
a disc-shaped body consisting of a first dielectric material having a first dielectric constant;
an annular cavity defined within the disc-shaped body, the annular cavity configured to contain a second dielectric material having a second dielectric constant greater than the first dielectric constant, the second dielectric material being a fluid.

14. The dielectric window of claim 13, wherein the disc-shaped body and the annular cavity are configured so that an efficiency of inductive coupling of power through the dielectric window is different for different radial sections of the dielectric window.

15. The dielectric window of claim 13, wherein the different radial sections include a first section through which power is inductively coupled through the first dielectric material alone, and a second section through which power is inductively coupled through both of the first and the second dielectric materials.

16. The dielectric window of claim 13, wherein the disc-shaped body spans a width of the process region, and wherein the annular cavity does not span the width of the process region.

17. The dielectric window of claim 13, wherein the annular cavity is positioned to be substantially disposed below a coil that inductively couples power into the process chamber.

18. The dielectric window of claim 13, wherein the disc-shaped body and the annular cavity reduce radial non-uniformity of plasma generated in the process chamber.

19. The dielectric window of claim 13, wherein the annular cavity has a substantially rectangular cross-section.
